(19) United States
(12) Patent Application Publication
(10) Pub. No.: US 2024/0377730 A1
(43) Pub. Date: Nov. 14, 2024

(54) RESIST COMPOSITION AND PATTERN FORMING PROCESS

(71) Applicant: Shin-Etsu Chemical Co., Ltd., Tokyo (JP)

(72) Inventors: Masaki Ohashi, Joetsu-shi (JP); Seiichiro Tachibana, Joetsu-shi (JP); Shun Kikuchi, Joetsu-shi (JP); Ryunosuke Handa, Joetsu-shi (JP)

(73) Assignee: Shin-Etsu Chemical Co., Ltd., Tokyo (JP)

(21) Appl. No.: 18/651,856

(22) Filed: May 1, 2024

(30) Foreign Application Priority Data
May 12, 2023 (JP) 2023-079324

(51) Int. Cl. G03F 7/004; G03F 7/20

(52) U.S. Cl. CPC G03F 7/0042; G03F 7/2004; G03F 7/2059

(57) ABSTRACT

The resist composition exhibits excellent sensitivity, resolution, and LWR when processed by photolithography using high-energy radiation, typically EB and EUV lithography, and a patterning process using the same. The resist composition comprises a specific tin compound and an organic solvent exhibits excellent sensitivity, resolution, and LWR when processed by photolithography using high-energy radiation.

### CROSS-REFERENCE TO RELATED APPLICATIONS

This non-provisional application claims priority under 35 U.S.C. § 119 (a) on Patent Application No. 2023-079324 filed in Japan on May 12, 2023, the entire contents of which are hereby incorporated by reference.

### TECHNICAL FIELD

This invention relates to a resist composition and a pattern forming process.

### BACKGROUND ART

While a higher integration density, higher operating speed and lower power consumption of LSIs are demanded to comply with the expanding IoT market, the effort to reduce the pattern rule is in rapid progress. In particular, logic devices drive forward the miniaturization technology. As the advanced miniaturization technology, microelectronic devices of 10-nm node are manufactured in a mass scale by the double, triple or quadro-patterning version of the ArF immersion lithography. The manufacture of 7-nm node devices by the next generation EUV lithography of wavelength 13.5 nm is investigated.

As the feature size is reduced, image blurs due to acid diffusion become a problem (see Non-Patent Document 1). To ensure resolution for fine patterns with a feature size of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having polymerizable olefin. With respect to the patterning of a resist film to a feature size of 16 nm et seq., it is believed impossible from the aspect of acid diffusion to form such a pattern from a chemically amplified resist composition. It would be desirable to have a non-chemically-amplified resist composition.

A typical non-chemically-amplified resist material is polymethyl methacrylate (PMMA). PMMA forms a positive resist material which increases solubility in organic solvent developer through the mechanism that the molecular weight becomes lower as a result of scission of the main chain upon EB or EUV exposure. There are drawbacks of low etch resistance and excessive outgassing upon exposure due to the lack of ring structure.

Hydrogensilsesquioxane (HSQ) forms a negative resist material which turns insoluble in alkaline developer through crosslinking by condensation reaction of silanol provoked by EB or EUV exposure. Also, chlorine-substituted calixarene functions as a negative resist material. Since these negative resist materials have a small molecular size prior to crosslinking and avoid any blur caused by acid diffusion, they exhibit a reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device.

As the means for reducing the influence of shot noise on the resist side, Patent Document 1 discloses an inorganic resist composition comprising an element having substantial EUV absorption. The sensitivity of this inorganic resist composition is relatively high, but still insufficient. Many problems remain unsolved including poor solubility in resist solvent, storage stability, and defectiveness.

Non-Patent Document 3 reports a negative resist composition comprising a tin compound. It is a non-chemically-amplified resist composition containing highly EUV-absorptive tin element. Although this resist composition is improved in stochastics and reaches a certain level of sensitivity and resolution, the improvements are still insufficient. The development of a further improved resist is strongly demanded.

### CITATION LIST

Patent Document 1: JP-A 2015-108781 (U.S. Pat. No. 9,366,960)
Non-Patent Document 1: SPIE Vol. 5039 p 1 (2003)
Non-Patent Document 2: SPIE Vol. 6520 p 65203L-1 (2007)
Non-Patent Document 3: SPIE Vol. 9051, p 90511B-1 (2014)

### SUMMARY OF THE INVENTION

An object of the invention is to provide a resist composition which exhibits excellent sensitivity, resolution, and LWR when processed by photolithography using high-energy radiation, typically EB and EUV lithography, and a patterning process using the same.

The inventors have found that a resist composition based on a tin cluster compound of specific structure has a high sensitivity, forms a resist film having a satisfactory resolution and improved LWR, and is thus quite useful in precise micropatterning.

In one aspect, the invention provides a resist composition comprising a tin compound having the formula (1) and an organic solvent.

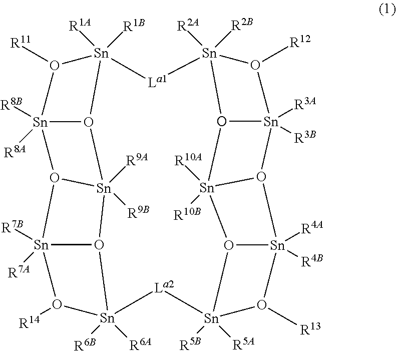

Herein R^{1A} to R^{10A} and R^{1B} to R^{10B} are each independently a C₁-C₂₀ hydrocarbyl group, R¹¹ to R¹⁴ are each independently hydrogen or a C₁-C₂₀ hydrocarbyl group, L^{a1} and L^{a2} are each independently a linking group.

In a preferred embodiment, L^{a1} and L^{a2} are each independently a group having any one of the formulae (2a) to (2d).

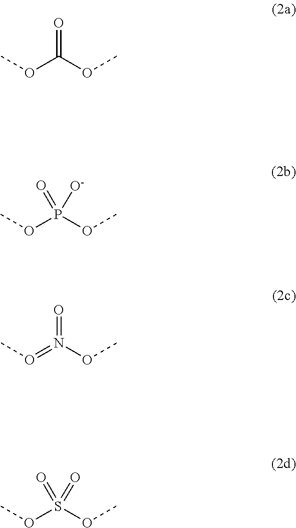

Herein the broken line designates a point of attachment to Sn.

In a preferred embodiment, R^{1A} to R^{10A} and R^{1B} to R^{10B} are selected from isopropyl, n-butyl, tert-butyl, and benzyl groups.

The resist composition may further comprise a surfactant.

In another aspect, the invention provides a pattern forming process comprising the steps of:
applying the resist composition defined herein onto a substrate to form a resist film thereon,
exposing the resist film to high-energy radiation, and
developing the exposed resist film in a developer.

Typically, the high-energy radiation is EB or EUV.

### Advantageous Effects of Invention

The resist composition exhibits both high sensitivity and resolution when processed by photolithography using high-energy radiation, typically EB and EUV lithography, forms small-size patterns with reduced LWR, and is thus quite useful in precise micropatterning.

### BRIEF DESCRIPTION OF THE DRAWINGS

FIG. 1 is a diagram showing the ¹H-NMR spectrum of tin compound M-1 in Synthesis Example 1.

FIG. 2 is a diagram showing the ¹¹⁹Sn-NMR spectrum of tin compound M-1 in Synthesis Example 1.

FIG. 3 is a SEM image of a line-and-space (LS) pattern of space width 20 nm and pitch 40 nm printed at Eop in Example 2-1.

FIG. 4 is a diagram showing the film thickness versus exposure dose relationship (contrast curve and PEB shrinkage) of a resist film formed in Example 3.

### DETAILED DESCRIPTION OF THE INVENTION

The terms “a” and “an” herein do not denote a limitation of quantity, but rather denote the presence of at least one of the referenced item. As used herein, the notation (Cₙ-Cₘ) means a group containing from n to m carbon atoms per group. In chemical formulae, Me stands for methyl, Et for ethyl, nBu for n-butyl, tBu for tert-butyl, iPr for isopropyl, and Bn for benzyl.

The abbreviations and acronyms have the following meaning.
EUV: extreme ultraviolet
EB: electron beam
Mw: weight average molecular weight
PEB: post-exposure bake
LWR: line width roughness
CDU: critical dimension uniformity

### [Resist Composition]

One embodiment of the invention is a resist composition comprising a specific tin compound and an organic solvent.

### [Tin Compound]

The tin compound has the formula (1). It is a main component of the resist composition. Herein, the main component means that its content is the highest among other components exclusive of the solvent.

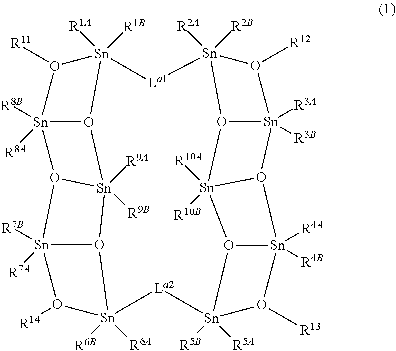

In formula (1), R^{1A} to R^{10A} and R^{1B} to R^{10B} are each independently a C₁-C₂₀ hydrocarbyl group, R¹¹ to R¹⁴ are each independently hydrogen or a C₁-C₂₀ hydrocarbyl group, L^{a1} and L^{a2} are each independently a linking group.

The C₁-C₂₀ hydrocarbyl group represented by R^{1A} to R^{10A}, R^{1B} to R^{10B} and R¹¹ to R¹⁴ may be saturated or unsaturated and straight, branched or cyclic. Examples thereof include C₁-C₂₀ alkyl groups such as methyl, ethyl, propyl, isopropyl, n-butyl, sec-butyl, tert-butyl, n-pentyl, tert-pentyl, n-hexyl, n-octyl, 2-ethylhexyl, n-nonyl, and n-decyl, C₃-C₂₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo [5.2.1.0^{2.6}]decyl, adamantyl, and adamantylmethyl, C₂-C₂₀ alkenyl groups such as vinyl and allyl, C₆-C₂₀ aryl groups such as phenyl and naphthyl, C₇-C₂₀ aralkyl groups such as benzyl and phenethyl, and combinations thereof.

Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonate ester bond, carbonate bond, carbamate bond, lactone ring, sultone ring, or carboxylic anhydride (—C(═O)—O—C(═O)—).

For availability of reactants and ease of production, R^{1A} to R^{10A} are preferably identical, and R^{1B} to R^{10B} are preferably identical. Most preferably, all R^{1A} to R^{10A} and RIB to R^{10B} are identical.

R^{1A} to R^{10A} and R^{1B} to R^{10B} are preferably selected from isopropyl, n-butyl, tert-butyl, and benzyl groups, more preferably from n-butyl, tert-butyl, and benzyl groups. R¹¹ to R¹⁴ are preferably hydrogen or methyl.

Preferred examples of the linking group represented by L^{a1} and L^{a2} include groups having the formulae (2a) to (2d).

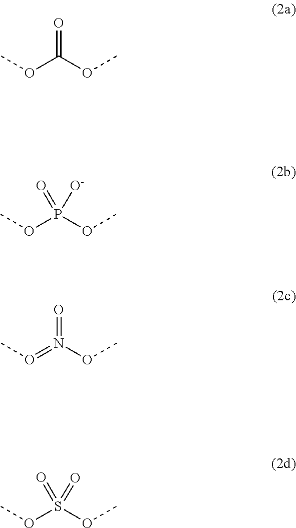

Herein the broken line designates a point of attachment to Sn.

Illustrative examples of the tin compound having formula (1) are shown below, but not limited thereto.

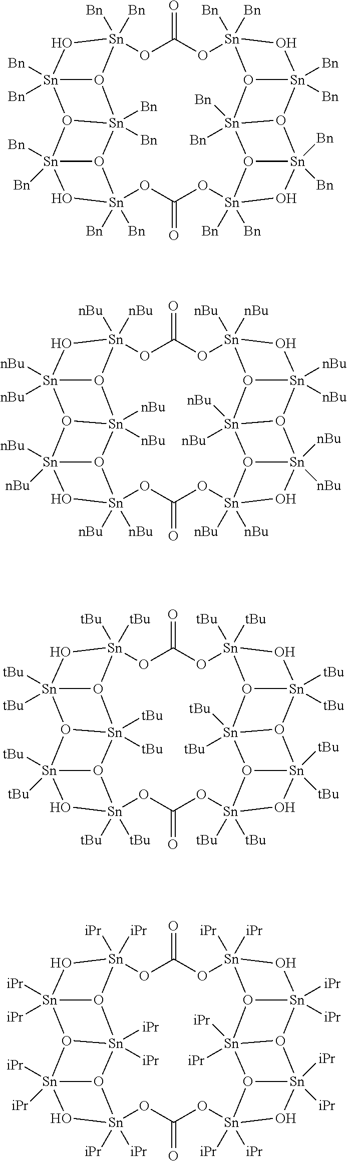

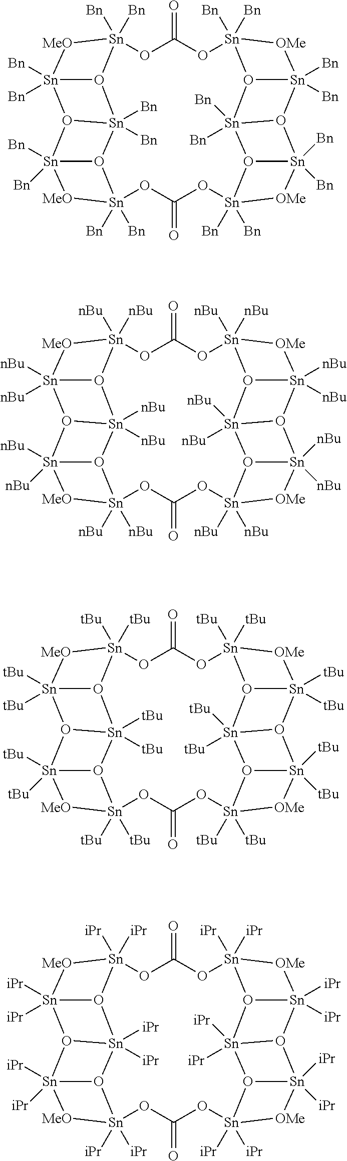

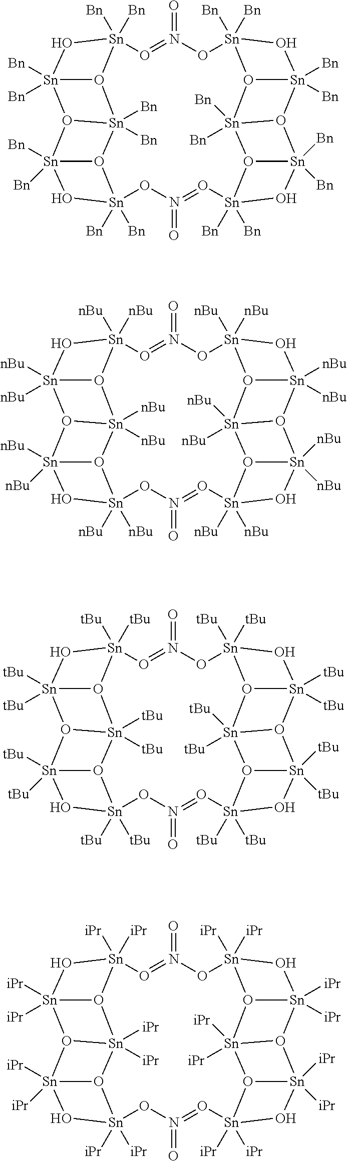

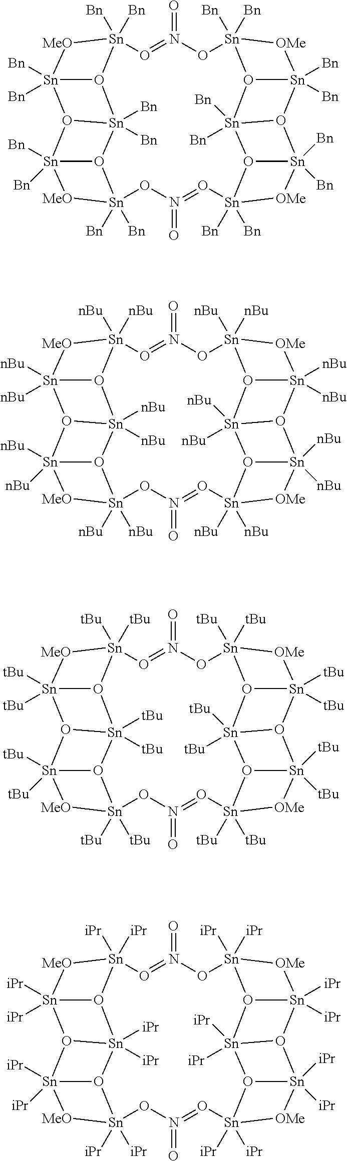

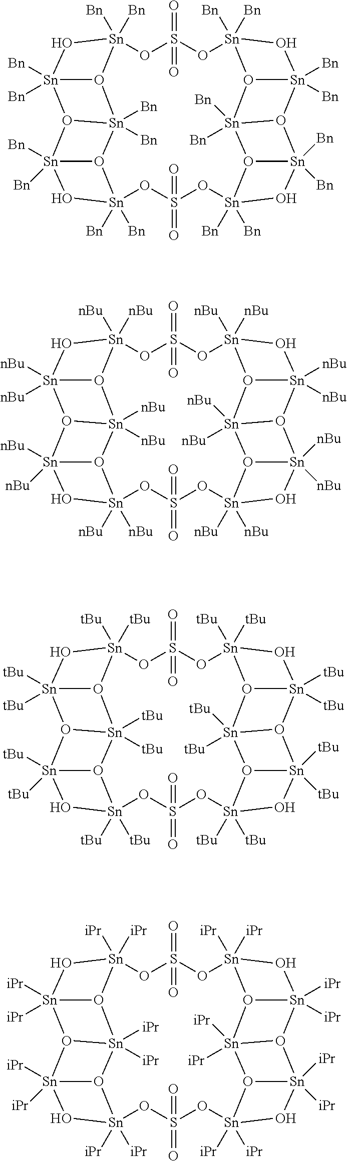

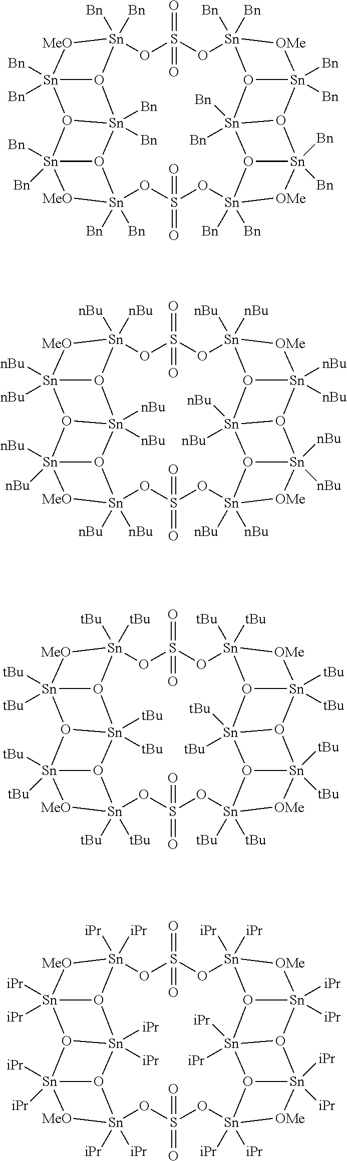

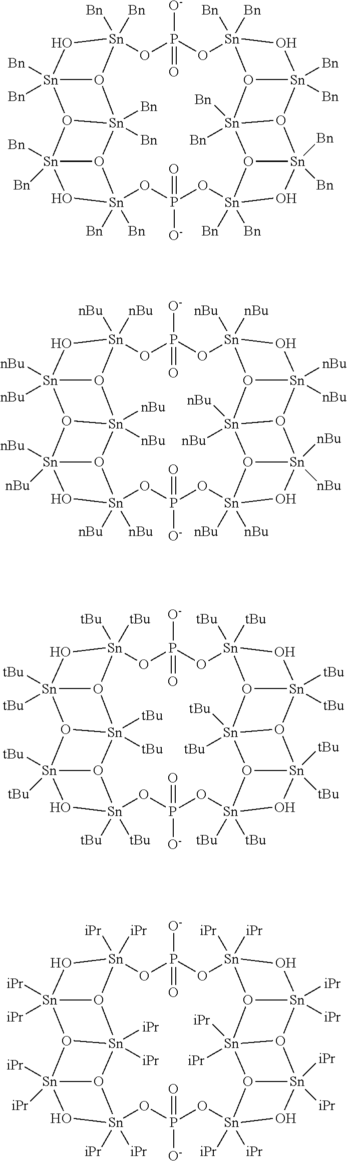

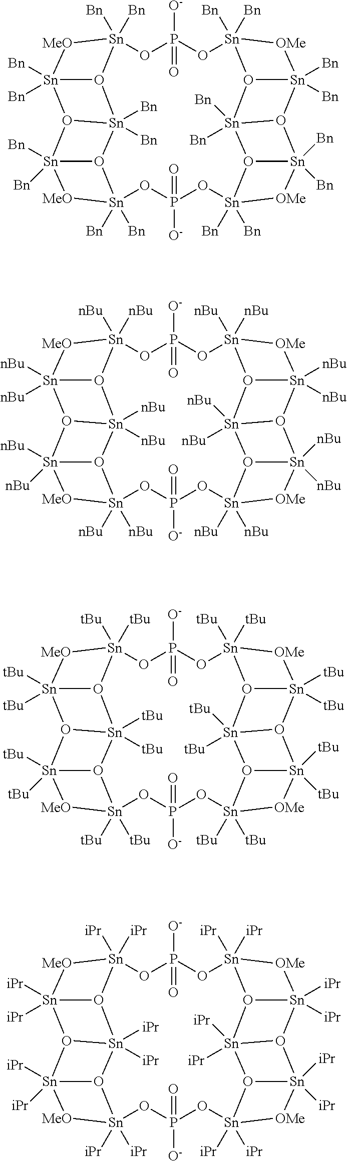

The tin compound having formula (1) may be used alone or in admixture of two or more. For enhancing the uniformity of the component, the tin compound is preferably used alone or in admixture of two.

The tin compound having formula (1) can be synthesized with reference to Z. Naturforsch. 2010, 65b, 1293-1300, and Inorg. Chim. Acta 357, (9), 2791-2797, 2004.

### [Organic Solvent]

The resist composition contains an organic solvent. The organic solvent is not particularly limited as long as the tin compound having formula (1) is dissolvable therein and a film can be formed from the resulting solution. Suitable organic solvents include ketones such as cyclohexanone and methyl 2-n-pentyl ketone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, cyclohexyl acetate, tert-butyl propionate, propylene glycol mono-tert-butyl ether acetate; lactones such as γ-butyrolactone; carboxylic acids such as acetic acid and propionic acid; aromatic solvents such as toluene, xylene, cresol, anisole, and benzotrifluoride, and mixtures thereof.

The amount of the organic solvent used is preferably 200 to 20,000 parts by weight, more preferably 500 to 10,000 parts by weight per 100 parts by weight of the tin compound having formula (1).

The resist composition of the invention is a so-called molecular resist composition, that is, a resist composition which contains a low molecular weight compound as the main component, but not a base polymer which is used in conventional polymeric resist compositions. The resist composition changes its solvent solubility via photo-decomposition of the tin compound as main component and subsequent crosslinking reaction, and turns insoluble in the developer. Since the relevant reaction is not a catalytic reaction, the resist composition functions as a non-chemically-amplified resist composition. This leads to an improvement in maximum resolution as compared with conventional chemically amplified resist compositions based on multi-component polymers. When processed by EUV lithography, the resist composition is improved in stochastics, sensitivity and LWR because tin atoms having a high EUV absorptivity are contained.

The tin compound is a 10-nucleus complex of tin, that is, cluster compound. Because of a thermally stable cluster structure, the compound is also improved in storage stability. Non-Patent Document 3 describes the tin cluster compound in the form of a 12-nucleus complex which has the advantage of thermal stability, but a low solubility in organic solvent. When a resist composition containing a tin compound is stored over a long term, there are concerns about precipitation and degradation of film-forming ability with the lapse of time. By contrast, the inventive tin compound is improved in solvent solubility. Although the reason is not well understood, presumably it contributes to solvent solubility that the rigidity of the cluster structure is mitigated by the inclusion of L^{a1} and L^{a2} (i.e., linkers) in formula (1). In addition, the tin compound is characterized by substantial film shrinkage during light exposure. The pattern printed after exposure is contracted by shrinkage. Defects such as pattern collapse and breakage are eliminated from the thus densified fine lines. The maximum resolution is thus improved. It is noted that the film shrinkage is preferably at least 20%, more preferably at least 30%, even more preferably at least 50%.

The resist composition may further contain a surfactant as another component. The surfactant is preferably selected from fluorochemical and silicone-based surfactants. Exemplary surfactants are described, for example, in US 2008/0248425, paragraph [0276]. Also useful are surfactants other than the fluorochemical and silicone-based surfactants, as described, for example, in US 2008/0248425, paragraph [0280]. When used, the surfactant is preferably present in an amount of 0.001 to 20 parts by weight, more preferably 0.1 to 10 parts by weight per 100 parts by weight of the tin compound. The surfactant may be used alone or in admixture of two or more.

### [Pattern Forming Process]

When the resist composition is used in the fabrication of various integrated circuits, any well-known lithography techniques are applicable. For example, the invention provides a pattern forming process comprising the steps of applying the resist composition onto a substrate to form a resist film thereon, exposing the resist film to high-energy radiation, and developing the exposed resist film in a developer.

First, the resist composition is applied onto a substrate for integrated circuit fabrication (e.g., Si, SiO₂, SIN, SION, TIN, WSi, BPSG, SOG, or organic antireflective coating) or a substrate for mask circuit fabrication (e.g., Cr, CrO, CrON, MoSi₂, or SiO₂) by any suitable technique such as spin coating, roll coating, flow coating, dip coating, spray coating or doctor coating. The coating is prebaked on a hot plate at a temperature of preferably 60 to 150° C. for 10 seconds to 30 minutes, more preferably at 80 to 120° C. for 30 seconds to 20 minutes to form a resist film having a thickness of 0.01 to 2 μm.

Next the resist film is exposed to high-energy radiation. The radiation is selected from among UV, deep UV, EB, EUV, X-ray, soft X-ray, excimer laser radiation, γ-ray, and synchrotron radiation. On use of UV, deep UV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 200 mJ/cm², more preferably about 10 to 100 mJ/cm². On use of EB as the high-energy radiation, imagewise writing is performed directly or through a mask having the desired pattern so as to reach a dose of preferably about 0.1 to 5,000 μC/cm², more preferably about 0.5 to 4,000 μC/cm². The resist composition is best suited in micropatterning using KrF excimer laser, ArF excimer laser, EB, EUV, X-ray, soft X-ray, γ-ray or synchrotron radiation, especially EB or EUV as the high-energy radiation.

If necessary, the resist film is post-exposure baked (PEB) for promoting or completing the reaction subsequent to photo-decomposition. Preferably PEB is performed on a hot plate or in an oven at 30 to 200° C. for 10 seconds to 30 minutes, more preferably at 60 to 180° C. for 30 seconds to 20 minutes.

The exposure or PEB step is followed by organic solvent development. The exposed resist film is developed in a developer by a standard technique such as dip, puddle or spray technique for 3 seconds to 3 minutes, preferably 5 seconds to 2 minutes to form the desired pattern. Since the resist composition is of negative tone, the exposed region of the resist film is insolubilized and the unexposed region is dissolved away in the developer.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether.

Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne.

Suitable aromatic solvents include toluene, xylene, ethylbenzene, isopropylbenzene, t-butylbenzene and mesitylene.

Rinsing is effective for preventing the resist pattern from collapse or reducing defect formation. Rinsing is not essential. By omitting rinsing, the amount of the solvent used is saved.

### EXAMPLES

Examples of the invention are given below by way of illustration and not by way of limitation. The abbreviation “pbw” is parts by weight. For spectroscopic analysis, the following instruments were used.

IR: NICOLET 6700 by Thermo Fisher Scientific Inc.

¹H-NMR: ECA-500 by JEOL Ltd.

### [1] Synthesis of Tin Compound

### [Synthesis Example 1] Synthesis of Tin Compound M-1

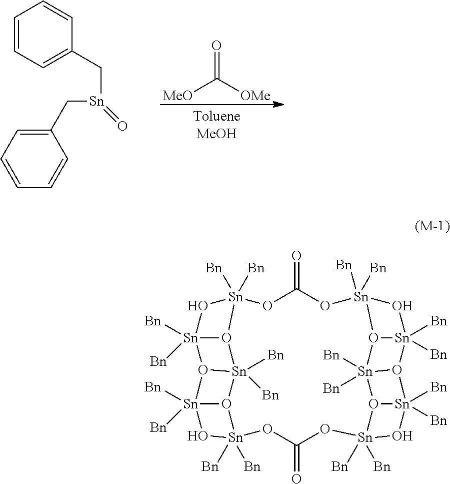

A mixture of 1.6 g of dibenzyl dichlorooxide, 1.5 g of dimethyl carbonate, 1.1 g of methanol, and 60 g of toluene was stirred at 110° C. for 3 hours. The solution was cooled to room temperature, filtered to remove the insoluble, and concentrated under reduced pressure. Toluene was added to the concentrate, which was heated for dissolution. The solution was cooled to room temperature and allowed to recrystallize for purification, obtaining 0.9 g of the desired tin compound M-1 (yield 55%).

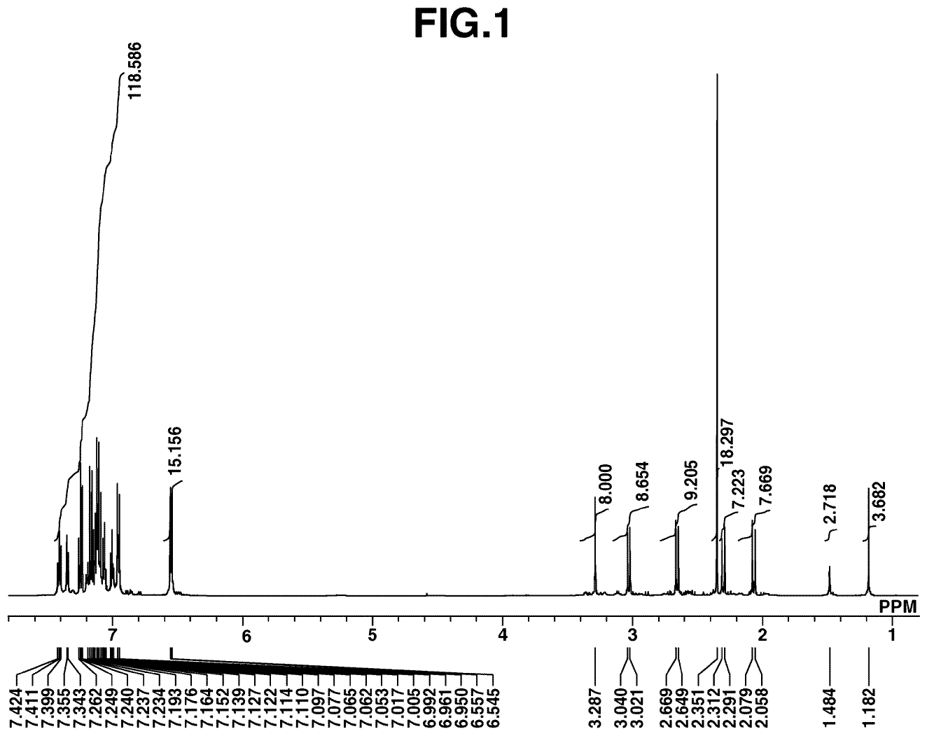

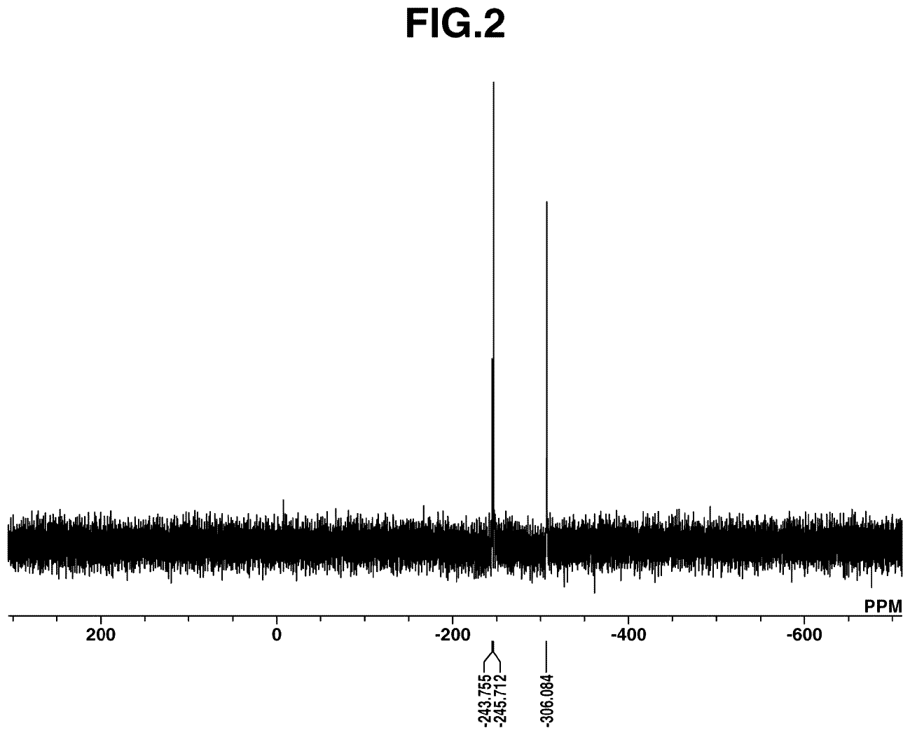

The IR spectroscopy data of tin compound M-1 are shown below. FIGS. 1 and 2 show the results of ¹H- and ¹¹⁹Sn-NMR/CDCl₃ spectroscopy of M-1. In the ¹H-NMR spectroscopy, the residual solvent (toluene) was observed.

IR (D-ATR): 3635, 3079, 3057, 3023, 2929, 1599, 1538, 1492, 1451, 1405, 1366, 1210, 1115, 1052, 1029, 756, 731, 709, 698, 618, 518, 464, 455 cm⁻¹

### [Synthesis Example 2] Synthesis of Tin Compound M-2

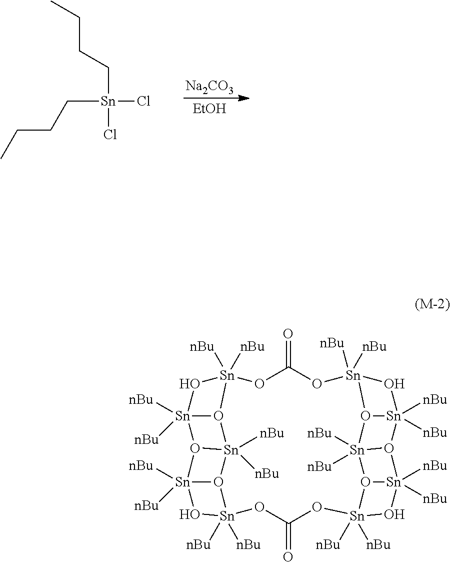

A mixture of 1.0 g of di-n-butyltin dichloride, 0.3 g of sodium carbonate, and 100 g of 95 wt % ethanol aqueous solution was stirred at 60° C. overnight. The solution was cooled to room temperature and filtered to remove the insoluble. The insoluble was washed with 30 wt % ethanol aqueous solution. The powder after washing was dried under reduced pressure, obtaining 0.6 g of the desired tin compound M-2 (yield 67%).

The IR spectroscopy data of tin compound M-2 are shown below.

IR (D-ATR): 2958, 2925, 2871, 2858, 1510, 1464, 1378, 1287, 1157, 1079, 1020, 965, 870, 826, 678, 640, 487 cm⁻¹

### [Synthesis Example 3] Synthesis of Tin Compound M-3

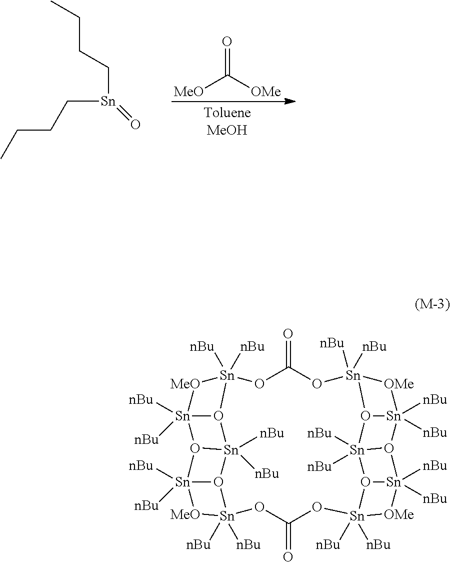

A mixture of 2.5 g of di-n-butyltin oxide, 0.9 g of dimethyl carbonate, 20 g of toluene, and 0.2 g of methanol was stirred at 110° C. for 1 hour. The solution was cooled to room temperature and concentrated under reduced pressure. The concentrate was washed with methanol. The resulting powder was heat dried under reduced pressure, obtaining 2.2 g of the desired tin compound M-3 (yield 83%).

The IR spectroscopy data of tin compound M-3 are shown below.

IR (D-ATR): 2956, 2922, 2871, 2855, 2801, 1541, 1463, 1419, 1376, 1068, 669, 605, 577, 534 cm⁻¹

### [2] Preparation of Resist Composition

### Example 1-1 and Comparative Examples 1-1 and 1-2

Each of inventive resist composition R-1 and comparative resist compositions CR-1 and CR-2 was prepared by mixing and dissolving selected components in a solvent in accordance with the recipe shown in Table 1, and filtering the solution through a Teflon® filter having a pore size of 0.2 μm.

TABLE 1

| | Resist | Component | Component | Component | Component | Solvent | Solvent |
|---|---|---|---|---|---|---|---|
| | composition | (A) (pbw) | (B) (pbw) | (C) (pbw) | (D) (pbw) | 1 (pbw) | 2 (pbw) |
| Example 1-1 | R-1 | M-1 | — | — | — | PGMEA | DAA |
| | | (42) | | | | (1,500) | (600) |
| Comparative | CR-1 | P-1 | PAG-1 | Q-1 | SF-1 | PGMEA | DAA |
| Example 1-1 | | (65) | (19) | (1.3) | (0.01) | (1,500) | (600) |
| Comparative | CR-2 | CM-1 | — | — | — | PGMEA | DAA |
| Example 1-2 | | (42) | | | | (1,500) | (600) |

In Table 1, comparative resist composition CR-1 is a chemically amplified resist composition containing base polymer P-1, photoacid generator PAG-1, sensitivity modifier Q-1, and surfactant SF-1, which are identified below.
P-1: p-hydroxystyrene/1-methylcyclopentyl methacrylate copolymer

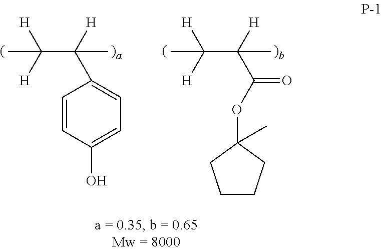

PAG-1: triphenylsulfonium 2-(adamantane-1-carbonyloxy)-1,1,3,3,3-pentafluoropropane-1-sulfonate

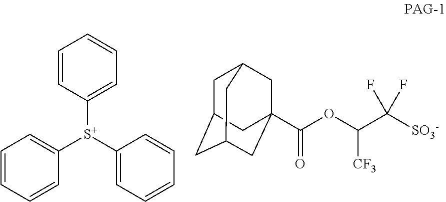

Q-1:2-morpholinoethyl laurate

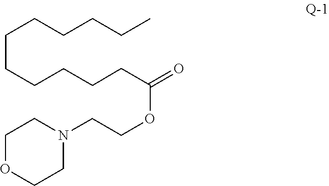 [SMILES: CCCCCCCCCCCC(=O)OCCN1CCOCC1]

SF-1: PF-636 (Omnova Solutions Inc.)

In Table 1, comparative resist composition CR-2 is a non-chemically-amplified resist composition containing tin compound CM-1 which was synthesized according to the teaching of Angewandte Chemie, International Edition (2017), 56 (34), 10140-10144. Its structure is shown below.

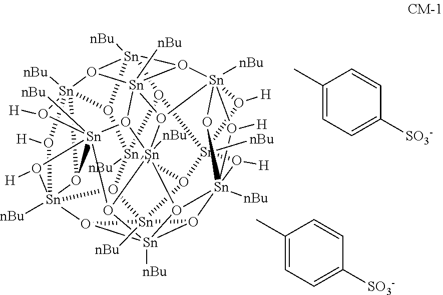

In Table 1, PGMEA is propylene glycol monomethyl ether acetate and DAA is diacetone alcohol.

### [3] EB Lithography Test

### (1) Evaluation of Sensitivity, LWR and Maximum Resolution

### Example 2-1 and Comparative Examples 2-1 and 2-2

An antireflective coating of 60 nm thick (DUV-42 by Nissan Chemical Industries, Ltd.) was formed on a silicon substrate. Each of the resist compositions R-1, CR-1 and CR-2 was spin coated on the ARC, and baked on a hotplate at 100° C. for 60 seconds to form a resist film of 40 nm thick. The resist film was exposed to EB on an EB lithography system (ELS-F125, Elionix Co., Ltd., accelerating voltage 125 kV), baked (PEB) on a hotplate at the temperature shown in Table 2 for 60 seconds, and developed in the developer shown in Table 2 for 30 seconds to form a pattern. Example 2-1 and Comparative Example 2-2 showed negative tone performance in that the resist film in the exposed region was left. Comparative Example 2-1 showed positive tone performance in that the resist film in the unexposed region was left. As a result, line-and-space (LS) patterns of negative or positive tone having a space width of 20 nm and a pitch of 40 nm were obtained.

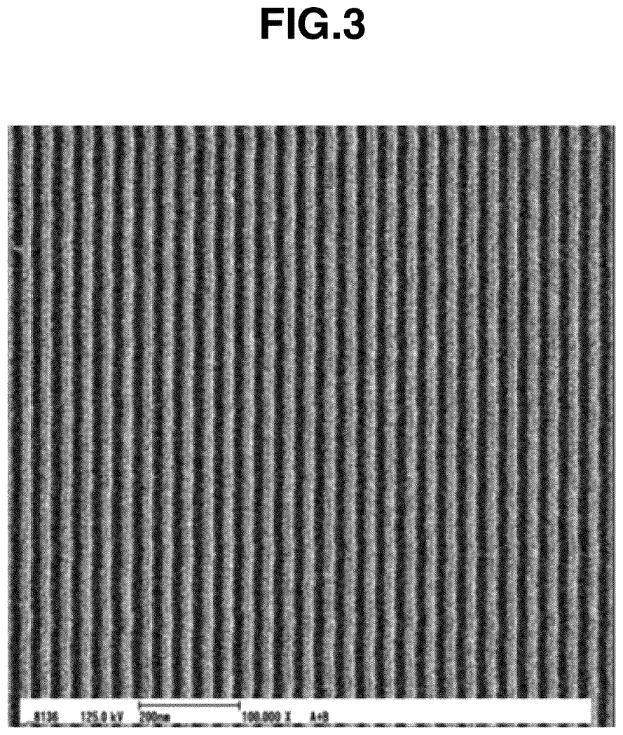

The LS pattern was observed under an electron microscope CD-SEM (CG-5000 by Hitachi High-Technologies Corp.). The LS pattern was evaluated for sensitivity, LWR, and maximum resolution by the following methods. The results are shown in Table 2. FIG. 3 is a SEM image of the LS pattern having space width 20 nm and pitch 40 nm printed at Eop in Example 2-1.

### [Evaluation of Sensitivity]

The optimum dose Eop (μC/cm²) which provided a LS pattern with a space width of 20 nm and a pitch of 40 nm was determined and reported as sensitivity.

### [Evaluation of LWR]

For the LS pattern formed by exposure in the optimum dose Eop, the space width was measured at longitudinally spaced apart 10 points, from which a 3-fold value (30) of the standard deviation (o) was determined and reported as LWR. A smaller value of 30 indicates a pattern having a lower roughness and more uniform space width.

### [Evaluation of Maximum Resolution]

The minimum line width (nm) of the LS pattern which remains separate at the optimum dose Eop is reported as maximum resolution.

TABLE 2

| | Resist | PEB | | Eop | | Maximum |
|---|---|---|---|---|---|---|
| | compo- | temp. | | (μC/ | LWR | resolution |
| | sition | (° C.) | Developer | cm²) | (nm) | (nm) |
| Example 2-1 | R-1 | 150 | 2-heptanone | 2,600 | 3.6 | 12 |
| Comparative | CR-1 | 90 | 2.38 wt % | 560 | 5.1 | 18 |
| Example 2-1 | | | TMAH | | | |
| | | | aqueous | | | |
| | | | solution | | | |
| Comparative | CR-2 | 170 | 2-heptanone | 3,200 | 4.7 | 16 |
| Example 2-2 | | | | | | |

It is evident from Table 2 that the resist composition within the scope of the invention is improved in LWR and maximum resolution when a negative pattern is formed by EB lithography and organic solvent development.

### (2) Evaluation of Contrast Curve and PEB Shrinkage

### Example 3

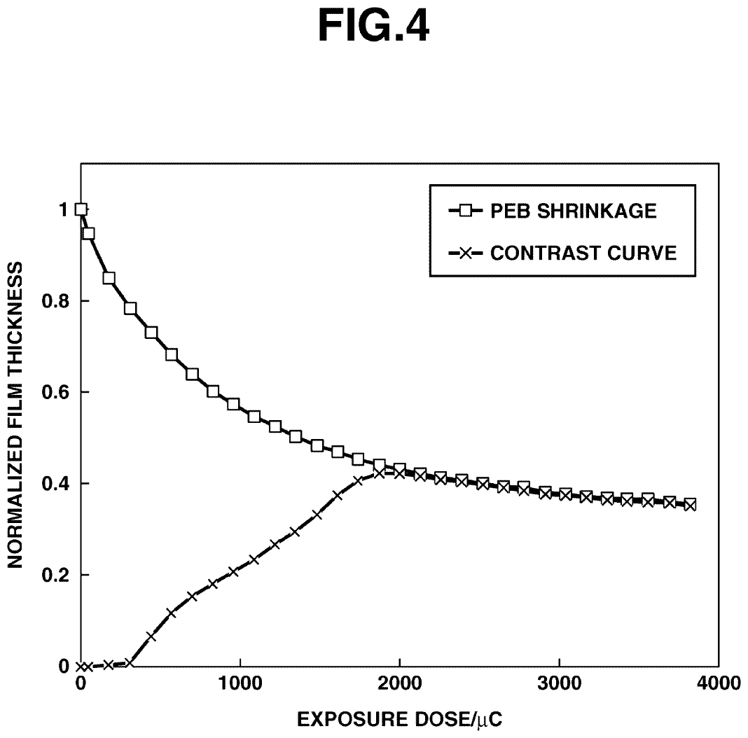

The resist composition R-1 was spin coated onto a 60-nm ARC (DUV-42 by Nissan Chemical Industries, Ltd.) on a silicon substrate and prebaked on a hotplate at 100° C. for 60 seconds to form a resist film of 40 nm thick. The resist film was exposed to EB on an EB lithography system (ELS-F125, Elionix Co., Ltd.) at an accelerating voltage of 50 kV and a dose varying in the range of 3 to 3,800 C/cm². The resist film was then baked (PEB) on a hotplate at 150° C. for 60 seconds. The thickness of the resist film was measured, from which PEB shrinkage was computed. The resist film was developed in 2-heptanone for 30 seconds, after which the thickness of the developed film was measured. The relationship of film thickness versus exposure dose is plotted in FIG. 4 (contrast curve and PEB shrinkage).

It is evident from FIG. 4 that as the exposure dose increases, PEB shrinkage increases and the film becomes more insoluble.

Although the resist composition shows a low sensitivity in the EB lithography, it is expected that the resist composition, which contains highly EUV absorptive tin atoms in a high concentration, exhibits a considerably high sensitivity in the EUV lithography.

Japanese Patent Application No. 2023-079324 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a tin compound having the formula (1) and an organic solvent, 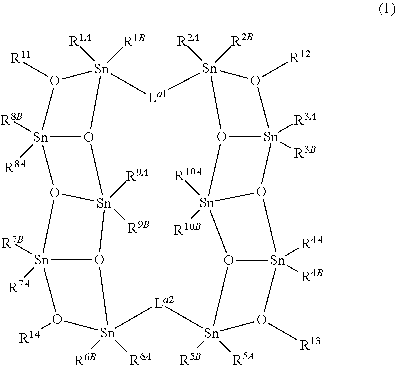
wherein R^{1A} to R^{10A} and R^{1B} to R^{10B} are each independently a C₁-C₂₀ hydrocarbyl group,
R¹¹ to R¹⁴ are each independently hydrogen or a C₁-C₂₀ hydrocarbyl group,
L^{a1} and L^{a2} are each independently a linking group.

2. The resist composition of claim 1 wherein L^{a1} and L^{a2} are each independently a group having any one of the formulae (2a) to (2d): 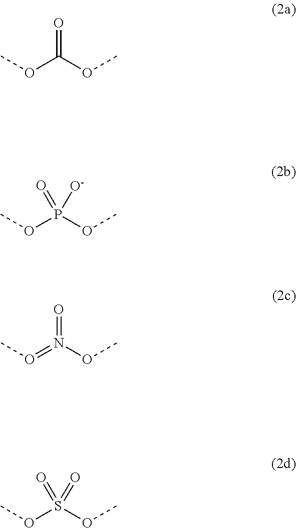
wherein the broken line designates a point of attachment to Sn.

3. The resist composition of claim 1 wherein R^{1A} to R^{10A} and R^{1B} to R^{10B} are selected from isopropyl, n-butyl, tert-butyl, and benzyl groups.

4. The resist composition of claim 1, further comprising a surfactant.

5. A pattern forming process comprising the steps of:
applying the resist composition of claim 1 onto a substrate to form a resist film thereon,
exposing the resist film to high-energy radiation, and
developing the exposed resist film in a developer.

6. The process of claim 5 wherein the high-energy radiation is EB or EUV.
